(19) United States
(12) Patent Application Publication
(10) Pub. No.: US 2011/0284979 A1
(43) Pub. Date: Nov. 24, 2011

(54) SOLID-STATE IMAGING DEVICE AND METHOD OF MANUFACTURING SAME

(75) Inventor: Ikuo MIZUNO, Kyoto (JP)

(73) Assignee: PANASONIC CORPORATION, Osaka (JP)

(21) Appl. No.: 13/105,317

(22) Filed: May 11, 2011

(30) Foreign Application Priority Data
May 20, 2010 (JP) 2010-116796

(51) Int. Cl. H01L 31/0232; H01L 31/18

(52) U.S. Cl. 257/432; 438/57; 257/E31.127; 257/E31.001

(57) ABSTRACT

A solid-state imaging device according to an aspect of the present invention includes: a semiconductor substrate; and a plurality of light-receiving units formed in a matrix in the semiconductor substrate and converting incident light into signal charges, and each of the convex parts is positioned corresponding to one of the light-receiving units and formed integrally with the semiconductor substrate.

### BACKGROUND OF THE INVENTION

(1) Field of the Invention

The present invention relates to solid-state imaging devices and a method of manufacturing the same.

(2) Description of the Related Art

Solid-state imaging devices represented by charge coupled device (CCD) solid-state imaging devices have been widely used as image sensors of imagers such as digital still cameras and digital video cameras, and there is an ever increasing demand for such solid-state imaging devices. In recent years, there has been a very high demand for an increase in the number of imaging pixels, and it is therefore necessary to increase the density of a pixel array and furthermore to downsize pixels.

However, when the size of pixels is reduced, the amount of incident light on the pixels decreases, which causes a problem of deterioration in sensitivity characteristic of a light-receiving unit of each of the pixels.

In view of this, there is a technique for improving efficiency of light collection to light-receiving units using on-chip lenses provided on color filters above light-receiving units. However, improvement of light collection efficiency only using on-chip lenses with a solid-state imaging device having pixels of, for example, 4 μm×4 μm or smaller is approaching a limit.

In this circumstance, as a new technique to attain the above improvement of the light collection efficiency, an additional lens (in-layer lens) fabricated from a light-transmissive material film is formed in a layer between the on-chip lens and the light-receiving unit to further improve the light collection efficiency (refer to Japanese Unexamined Patent Application Publication No. 61-287263, for example).

This in-layer lens is formed in an inter-layer film right above the light-receiving unit that performs photoelectric conversion, and guides incident light on this in-layer lens, to the light-receiving unit, by refracting the light by the top or bottom interface of this in-layer lens as in the case of the on-chip lens.

Another disclosed technique forms an optical waveguide by forming a hole in a planarizing film at a position right above the light-receiving unit and thereafter filling the hole with a high refractive material so that light is totally reflected on the interface between the planarizing film and a high refractive film serving as the optical waveguide, and thereby received by the light-receiving unit (refer to Japanese Unexamined Patent Application Publication No. 2003-060179, for example).

Pixels, however, have been further downsized in recent years and even a solid-state imaging device having a pixel size of 2×2 μm or less, for example, has been proposed. Since such downsizing of the pixels accompanies a decrease in the distance between a charge transfer unit and an open end of the light-receiving unit, the increase in the efficiency of light collection to the light-receiving unit imposes a problem of increasing probability of smears which are generated due to light brought into the charge transfer unit. In the case of using the in-layer lens, it is necessary to increase the lens curvature in order to increase the light collection efficiency, with the result that the collected light is in focus above a surface of the light-receiving unit. This increases light components which are obliquely incident on the light-receiving unit, causing light to be more likely to be brought into the charge transfer unit. In order to reduce smears, it is necessary to decrease the light collection efficiency on the contrary to reduce the obliquely incident light, which causes another problem of degrading sensitivity.

Also in the case of using the optical waveguide, the light spreads out at a lower end of the waveguide and enters the light-receiving unit, with the result that the light is likewise more likely to be brought into the charge transfer unit and is thus more likely to generate smears. This means that, with either technique of the in-layer lens or the optical waveguide, it is impossible to achieve satisfactory results for both smears and sensitivity at the same time.

### SUMMARY OF THE INVENTION

The present invention has been devised to solve the above problems, and an object of the present invention is to provide a solid-state imaging device with reduced degradation of smear characteristics and with high sensitivity and to provide a method of manufacturing the solid-state imaging device.

In order to achieve the above object, a solid-state imaging device according to an aspect of the present invention includes: a semiconductor substrate; and a plurality of light-receiving units formed in a matrix in the semiconductor substrate and configured to convert incident light into signal charges, wherein the semiconductor substrate includes a plurality of convex parts, each of which protrudes from a surface of the semiconductor substrate and has a smooth curved surface, and each of the convex parts is positioned corresponding to one of the light-receiving units and formed integrally with the semiconductor substrate.

With this structure, the solid-state imaging device according to an aspect of the present invention exhibits a lens effect because a convex part of a surface of the semiconductor substrate has a curved surface which is upwardly convex. Consequently, light obliquely incident on the surface of the semiconductor substrate can be refracted by the convex part and thereby guided into the light-receiving unit at an angle closer to the vertical. Thus, the solid-state imaging device according to an aspect of the present invention is capable of improving the sensitivity while reducing degradation of the smear characteristics.

Furthermore, each of the light-receiving units may have a smooth curved surface which is upwardly convex.

Furthermore, a lens formed of a transparent film may further be provided above each of the convex parts.

With this structure, the solid-state imaging device according to an aspect of the present invention is capable of not only improving the light collection efficiency using a lens above the convex part, but also guiding light obliquely incident on the surface of the semiconductor substrate into the light-receiving unit at an angle closer to the vertical by refracting the light by the convex part. Thus, the solid-state imaging device according to an aspect of the present invention is capable of improving the sensitivity while reducing degradation of the smear characteristics.

Furthermore, the lens may include silicon nitride.

With this structure, it is possible to form a lens by an ordinary method of manufacturing a semiconductor. Thus, cost reduction can be achieved.

Furthermore, when measured in a direction parallel to the semiconductor substrate, an outer diameter of the lens may be equal to or greater than an outer diameter of each of the convex parts.

With this structure, the solid-state imaging device according to an aspect of the present invention is capable of effectively collecting, to the convex part, light incident on the lens. Thus, the solid-state imaging device according to an aspect of the present invention is capable of improving the sensitivity while reducing degradation of the smear characteristics.

Furthermore, the solid-state imaging device may further include a color filter provided above the semiconductor substrate, and the lens may be provided under the color filter.

Furthermore, the solid-state imaging device may further include a high refractive film provided above the semiconductor substrate for each of the light-receiving units and formed of a transparent film having a columnar shape; and a low refractive film covering a side surface of the high refractive film and having a refractive index lower than a refractive index of the high refractive film.

With this structure, the solid-state imaging device according to an aspect of the present invention has an optical wavelength above the light-receiving unit so that light can be totally reflected on the interface between a low refractive film and a high refractive film serving as the optical waveguide, and thereby guided to the surface of the semiconductor substrate, and is capable of guiding light obliquely incident on the surface of the semiconductor substrate into the light-receiving unit at an angle closer to the vertical by refracting the light by the surface of the semiconductor substrate. Thus, the solid-state imaging device according to an aspect of the present invention is capable of improving the sensitivity while reducing degradation of the smear characteristics.

Furthermore, the high refractive film may include silicon nitride.

With this structure, it is possible to form an optical waveguide by an ordinary method of manufacturing a semiconductor. Thus, cost reduction can be achieved.

Furthermore, the low refractive film may include silicon oxide.

With this structure, a low refractive film which is sufficiently different in the refractive index from a high refractive film can be formed by an ordinary method of manufacturing a semiconductor. Thus, cost reduction can be achieved.

Furthermore, an outer diameter of an end of the high refractive film on a side of each of the light-receiving units may be equal to or smaller than an outer diameter of each of the convex parts measured in a direction parallel to the semiconductor substrate.

With this structure, the solid-state imaging device according to an aspect of the present invention is capable of guiding the light which entered the surface of the semiconductor substrate from a light-receiving unit-side end of the high refractive film, into the light-receiving unit at an angle closer to the vertical by effectively refracting the light by the convex part. Thus, the solid-state imaging device according to an aspect of the present invention is capable of improving the sensitivity while reducing degradation of the smear characteristics.

A method of manufacturing a solid-state imaging device according to an aspect of the present invention includes: forming a plurality of convex parts in a matrix by forming an oxide film which varies in thickness measured from a surface of a semiconductor substrate, and then removing the oxide film, the convex parts protruding from the surface of the semiconductor substrate and each having a smooth curved surface; and forming, below the respective convex parts, a plurality of light-receiving units that convert incident light into signal charges.

With this, the method of manufacturing a solid-state imaging device according to an aspect of the present invention allows manufacturing, without using any special equipment but by an ordinary method of manufacturing a semiconductor, a solid-state imaging device including convex parts, each of which protrudes from a surface of a semiconductor substrate and is formed with a smooth curved surface.

Thus, the method of manufacturing a solid-state imaging device according to an aspect of the present invention allows manufacturing a solid-state imaging device capable of improving the sensitivity while reducing degradation of the smear characteristics.

It is to be noted that the present invention may be implemented as a semiconductor integrated circuit (LSI) which includes part or all of the functions of such a solid-state imaging device, and may also be implemented as a digital still camera or digital video camera which includes such a solid-state imaging device.

As above, the present invention provides a solid-state imaging device with reduced degradation of smear characteristics and with high sensitivity, and provides a method of manufacturing the solid-state imaging device.

### Further Information about Technical Background to This Application

The disclosure of Japanese Patent Application No. 2010-116796 filed on May 20, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is an enlarged plan view of a part of a solid-state imaging device according to the first embodiment;

FIG. 1B is a cross-section diagram showing a cross-section structure taken along line X-X′ of FIG. 1A;

FIG. 2 is a cross-section diagram showing a cross-section structure in a manufacturing process;

FIG. 3A is a top view showing the structure of FIG. 2(c);

FIG. 3B is an enlarged cross-section diagram of a part of the cross-section structure of FIG. 2(c);

FIG. 4A is a top view showing the structure of FIG. 2(d);

FIG. 4B is an enlarged cross-section diagram of a part of the cross-section structure of FIG. 2(d);

FIG. 5A is a top view showing the structure of FIG. 2(g);

FIG. 5B is an enlarged cross-section diagram of a part of the cross-section structure of FIG. 2(g);

FIG. 6A is an enlarged plan view of a part of a solid-state imaging device according to the second embodiment;

FIG. 6B is a cross-section diagram showing a cross-section structure taken along line X-X′ of FIG. 6A; and

FIG. 7 is a cross-section diagram showing a structure of a solid-state imaging device in which a light-receiving unit has a convex surface.

### DESCRIPTION OF THE PREFERRED EMBODIMENT(S)

With reference to the drawings, the following describes a solid-state imaging device and a method of manufacturing the solid-state imaging device according to embodiments of the present invention.

### First Embodiment

A solid-state imaging device according to the first embodiment includes: a semiconductor substrate; and a plurality of light-receiving units that are formed in a matrix in the semiconductor substrate and convert incident light into signal charges. The semiconductor substrate includes a plurality of convex parts, each of which protrudes from a surface of the semiconductor substrate and has a smooth curved surface. Each of the convex parts is positioned corresponding to one of the light-receiving units and formed integrally with the semiconductor substrate.

With this, the solid-state imaging device according to the first embodiment of the present invention exhibits a lens effect because the convex part of the surface of the semiconductor substrate has a curved surface that protrudes from the surface of the semiconductor substrate. Consequently, light obliquely incident on the surface of the semiconductor substrate can be refracted by the convex part and thereby guided into the light-receiving unit at an angle closer to the vertical. Thus, the solid-state imaging device according to the first embodiment of the present invention is capable of improving the sensitivity while reducing degradation of the smear characteristics.

Furthermore, the solid-state imaging device according to the first embodiment of the present invention further includes a lens formed of a transparent film above each of the convex parts. With this, it is possible to not only improve the light collection efficiency using the lens above the convex part, but also guide light obliquely incident on the surface of the semiconductor substrate into the light-receiving unit at an angle closer to the vertical by refracting the light by the convex part. Thus, the solid-state imaging device according to an aspect of the present invention is capable of improving the sensitivity while reducing degradation of the smear characteristics.

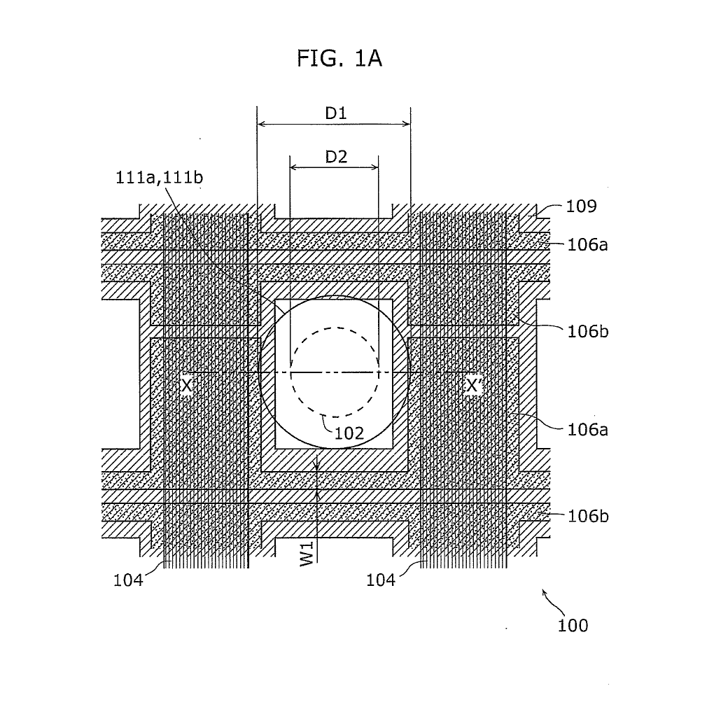

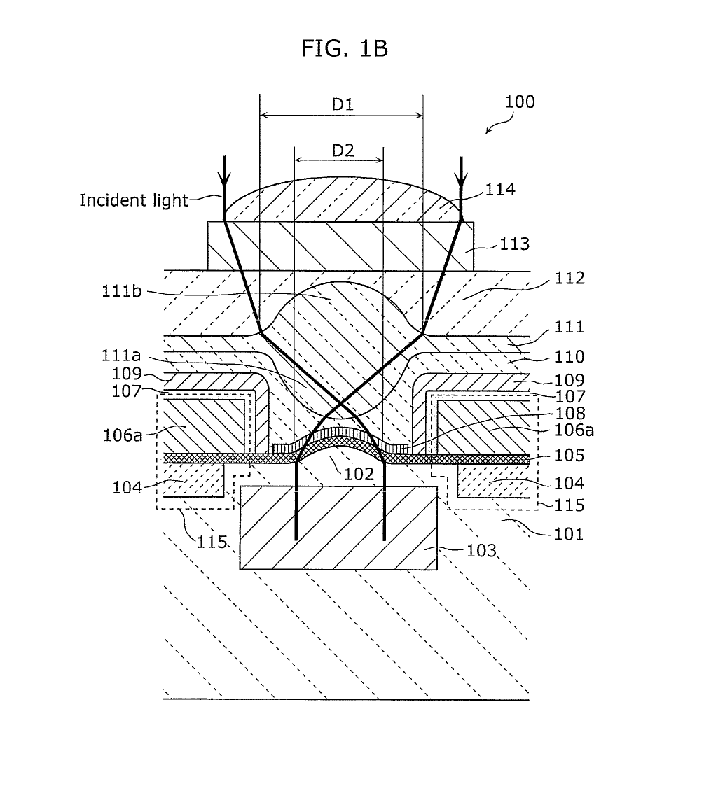

A structure of the solid-state imaging device 100 according to the first embodiment of the present invention is described below with reference to FIGS. 1A and 1B. The solid-state imaging device 100 shown in FIGS. 1A and 1B is a CCD solid-state imaging device.

FIG. 1A is an enlarged plan view of a part of the solid-state imaging device 100, and specifically is a plan view showing a structure centered on a single pixel of the solid-state imaging device 100. In this figure, a structure of a part of a pixel adjacent to the single pixel is also shown. FIG. 1B is a cross-section diagram showing a cross-section structure taken along line X-X′ of FIG. 1A, and the bold line in this figure indicates a path of the incident light.

The solid-state imaging device 100 includes a semiconductor substrate 101, a plurality of light-receiving units 103 arranged in matrix form, and a plurality of vertical charge transfer units 115 provided for respective columns. Specifically, the solid-state imaging device 100 includes: the semiconductor substrate 101 having convex parts 102 on a surface (on the upper surface of FIG. 1B); the light-receiving units 103 formed in the semiconductor substrate 101; a transfer channel 104; an insulating film 105; a transfer electrode 106; an insulating film 107; an antireflection film 108; a photo-shield shield 109; an insulating film 110; an in-layer lens 111; a planarizing film 112; a color filter 113; and a microscope lens 114.

The semiconductor substrate 101 is an n-type silicon substrate, for example. In a surface of this semiconductor substrate 101, a region for each of the light-receiving units 103 has a curvature of an upward convex curve. In other words, the semiconductor substrate 101 includes the convex part 102 that protrudes from the surface of the semiconductor substrate and has a smooth curved surface, and the convex part 102 is positioned corresponding to each of the light-receiving units 103 and integrally formed with the semiconductor substrate 101. It is to be noted that “integrally formed” herein indicates “made of the same material”. Consequently, light obliquely incident on the surface of the semiconductor substrate 101 can be refracted by the convex part 102 and thereby guided into the light-receiving unit 103 at an angle closer to the vertical. Thus, the solid-state imaging device 100 according to the first embodiment is capable of improving the sensitivity while reducing degradation of the smear characteristics.

Each of the light-receiving units 103 is formed in the semiconductor substrate 101 and photoelectrically converts the incident light into signal charges.

The transfer channel 104 constitutes a vertical charge transfer unit 115 together with a part of the insulating film 105, a plurality of first transfer electrodes 106a, and a plurality of second transfer electrodes 106b. This vertical charge transfer unit 115 reads the signal charges generated through the photoelectric conversion by the light-receiving units 103 arranged in a corresponding column, and transfers the read signal charges in the vertical direction (column direction), thereafter outputting them to a horizontal charge transfer unit (not shown). In FIG. 1A, the vertical direction (column direction) is a lengthwise direction while the horizontal direction (row direction) is a widthwise direction.

The transfer channel 104 is an n-type diffusion layer formed on a surface layer side of the semiconductor substrate 101. Furthermore, the transfer channel 104 extends in the vertical direction and is connected in the horizontal direction with the light-receiving units 103 arranged in a corresponding column. This transfer channel 104 is used to read the signal charges generated through the photoelectric conversion by the light-receiving units 103 arranged in a corresponding column, and transfer the read signal charges in the vertical direction, thereafter outputting them to the horizontal charge transfer unit (not shown).

The insulating film 105 is a gate insulating film and formed so as to cover the surface of the semiconductor substrate 101 in which the transfer channel 104 is formed. For example, the insulating film 105 is a silicon oxide film (silicon oxide) and has a thickness of preferably 10 nm to 100 nm and more preferably around 35 nm.

The first transfer electrodes 106a and the second transfer electrodes 106b are formed in the same level and change a voltage potential of the transfer channel 104 according to an applied voltage. This causes the signal changes in the transfer channel 104 to be transferred. Furthermore, the first transfer electrodes 106a and the second transfer electrodes 106b are formed above the transfer channel 104 with the insulating layer 105 therebetween. For example, the first transfer electrodes 106a and the second transfer electrodes 106b are formed of polysilicon. Furthermore, each of the first transfer electrodes 106a and the second transfer electrodes 106b has a thickness of preferably 0.1 μm to 0.3 μm and more preferably around 0.2 μm. Moreover, the first transfer electrodes 106a and the second transfer electrodes 106b are formed so as to cross the transfer channel 104.

In addition, for each of the light-receiving units 103, one of the first transfer electrodes 106a and one of the second transfer electrodes 106b are provided. The first transfer electrodes 106a and the second transfer electrodes 106b are arranged on the transfer channel 104 alternately along the vertical direction.

Furthermore, one of the first transfer electrodes 106a arranged in the same row is connected by a polysilicon layer with another one included in the vertical charge transfer unit 115 adjacent in the horizontal direction (row direction). In other words, adjacent two of the first transfer electrodes 106a which are arranged in the same row are connected with each other. A line for the part by which the first transfer electrodes 106a are connected with each other is formed so as not to overlap with the light-receiving unit 103 but to extend between the light-receiving units 103 adjacent in the vertical direction. For example, the width W1 of the line for the part which connects adjacent two of the first transfer electrodes 106a is preferably 0.1 μm to 0.5 μm, and more preferably around 0.25 μm.

The second transfer electrode 106b has the same structure as the first transfer electrode 106a.

In the descriptions below, the first transfer electrode 106a and the second transfer electrode 106b may be referred to as the transfer electrode 106 when these electrodes are not particularly distinguished from each other.

The insulating film 107 is formed on the transfer electrode 106 and insulates the transfer electrode 106 from the photo-shield film 109. This insulating film 107 is provided to prevent short-circuiting between the transfer electrode 106 and the photo-shield film 109, and has a thickness of around 0.03 μm to 0.15 μm. Furthermore, the insulating film 107 is formed of silicon oxide, for example.

The antireflection film 108 is formed on the insulating film 105 above the light-receiving unit 103 and prevents reflection of light incident on the light-receiving unit 103 (not shown in FIG. 1A). This antireflection film 108 is formed of a material having a refractive index higher than that of the insulating film 105, and is formed of silicon nitride, for example. The antireflection film 108 has a thickness of preferably 30 nm to 100 nm and more preferably around 50 nm.

The photo-shield film 109 is formed on upper and side parts of the transfer electrode 106 with the insulating film 107 therebetween and prevents light from entering the vertical charge transfer unit 115. This photo-shield film 109 is formed of a material having the property of blocking light and is formed of tungsten, for example. The photo-shield film 109 has a thickness of preferably 50 nm to 150 nm and more preferably around 100 nm.

The insulating film 110 is formed on the insulating film 105, the antireflection film 108, and the photo-shield film 109, and defines the height position of the in-layer lens 111 and the shape of the convex region below the in-layer lens 111. The height position of the in-layer lens 111 corresponds to the distance from the top surface of the light-receiving unit 103 to the center position in the thickness direction of the in-layer lens 111. The insulating film 110 is formed of an optically transparent material, and is formed of boro-phospho-silicate glass (BPSG), for example. The insulating film 110 has a thickness of preferably 50 nm to 200 nm and more preferably around 100 nm.

The in-layer lens 111 is formed on the insulating film 110 and collects light incident on the in-layer lens 111 by refracting the light by the top or bottom interface of the in-layer lens 111. Specifically, this in-layer lens 111 includes a first sub-lens part 111a that is convex downward and a second sub-lens part that is upwardly convex. This means that the first sub-lens part 111a and the second sub-lens part 111b function as a lens. In other words, the first sub-lens part 111a and the second sub-lens part 111b correspond to a lens according to an implementation of the present invention. Each of the first sub-lens part 111a and the second sub-lens part 111b has, for example, a substantially circular shape as shown in FIG. 1A.

This in-layer lens 111 is formed of an optically transparent material having a high refractive index, and preferably formed of silicon nitride. This allows the in-layer lens 111 to be formed in an ordinary method of manufacturing a semiconductor, which can reduce costs.

Furthermore, the diameter D1 of each of the first sub-lens part 111a and the second sub-lens part 111b of this in-layer lens 111 and the diameter D2 of the convex part 102 of the light-receiving unit 103 preferably have a relation represented by (Expression 1) below. Note that the diameter D1 is a diameter of each of the first sub-lens part 111a and the second sub-lens 111b, which is measured in the direction parallel to the semiconductor substrate 101, and the diameter D2 is a diameter of the convex part 102, which is measured in the direction parallel to the semiconductor substrate 101.

D1≧D2 (Expression 1)

This allows the light incident on the first sub-lens part 111a and the second sub-lens part 111b to be effectively collected on the convex part 102.

The planarizing film 112 is formed on the in-layer lens 111 so that the top surface of the planarizing film 112 becomes flat. This planarizing film 112 is formed of an optically transparent material.

The color filter 113 is formed on the planarizing film 112 and transmits, of the incident light on the color filter 113, light within a desired range of wavelengths only, thereby separating the incident light.

The microscope lens 114 is formed on the color filter 113 and guides light incident on the microscope lens 114 to the first sub-lens part 111a and the second sub-lens part 111b of the in-layer lens 111 by refracting the light by the top interface of the microscope lens 114.

As above, the solid-state imaging device 100 according to the present embodiment includes: the semiconductor substrate 101; and the plurality of light-receiving units 103 that are formed in a matrix in the semiconductor substrate 101 and convert incident light into signal charges. The semiconductor substrate 101 includes the plurality of convex parts 102, each of which protrudes from the surface of the semiconductor substrate 101 and has a smooth curved surface. Each of the convex parts 102 is positioned corresponding to one of the light-receiving units 103 and formed integrally with the semiconductor substrate 101.

With this, the solid-state imaging device 100 according to the first embodiment of the present invention exhibits a lens effect because the convex part 102 of the surface of the semiconductor substrate 101 has a curved surface which is upwardly convex. Consequently, light obliquely incident on the surface of the semiconductor substrate 101 can be refracted by the convex part 102 and thereby guided into the light-receiving unit 103 at an angle closer to the vertical. Thus, the solid-state imaging device 100 according to the first embodiment of the present invention is capable of improving the sensitivity while reducing degradation of the smear characteristics.

Furthermore, the solid-state imaging device 100 according to the first embodiment of the present invention further includes, on each of the convex parts 102, the first sub-lens part 111a and the second sub-lens part 111b, each of which is formed of a transparent film. With this, it is possible to not only improve the light collection efficiency using the first sub-lens part 111a and the second sub-lens part 111b above the convex part 102, but also guide light obliquely incident on the surface of the semiconductor substrate 101 into the light-receiving unit 103 at an angle closer to the vertical by refracting the light by the convex part 102. Thus, the solid-state imaging device 100 according to an aspect of the present invention is capable of improving the sensitivity while reducing degradation of the smear characteristics.

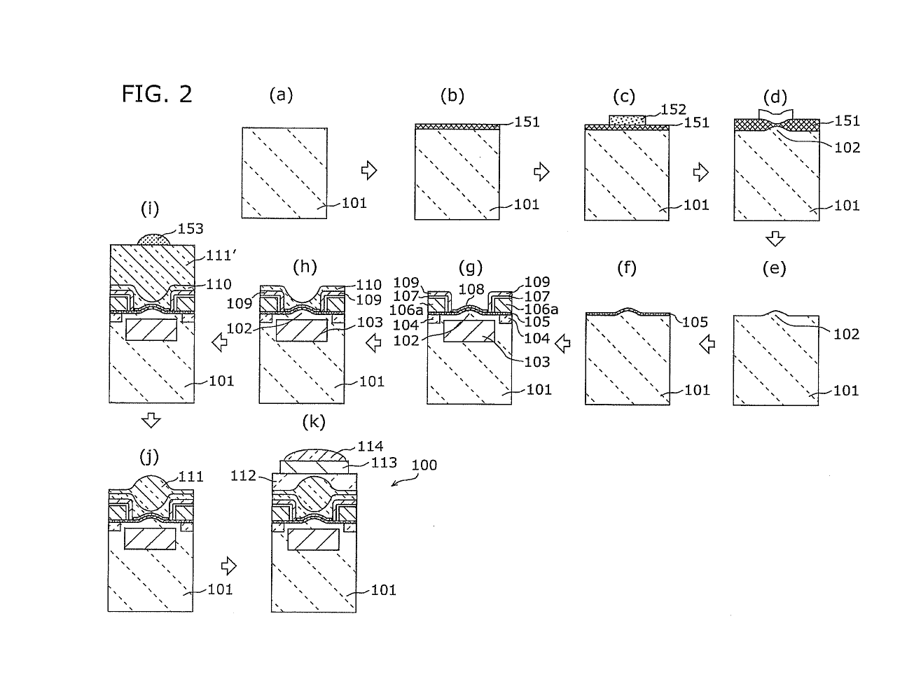

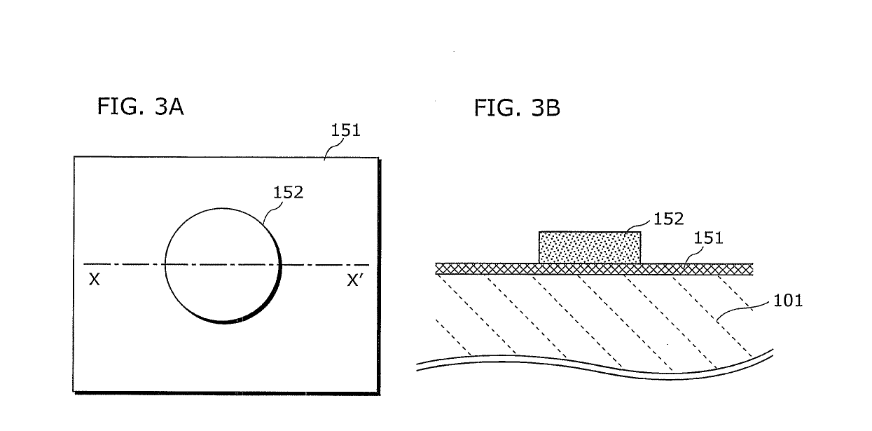

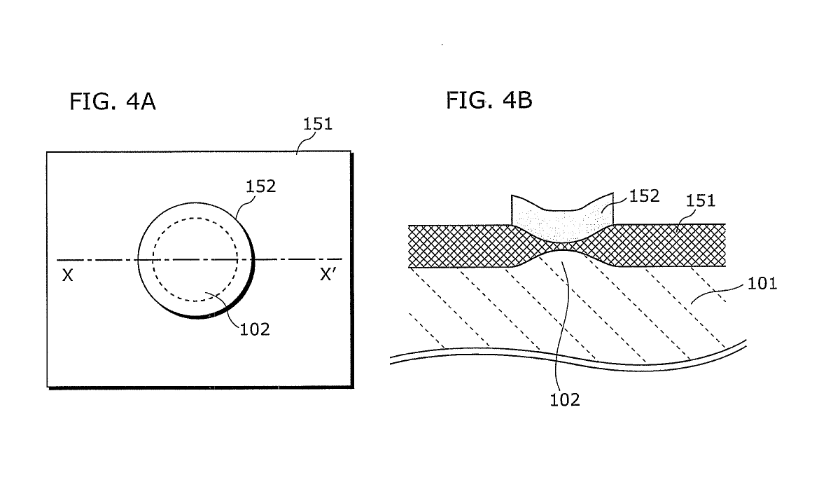

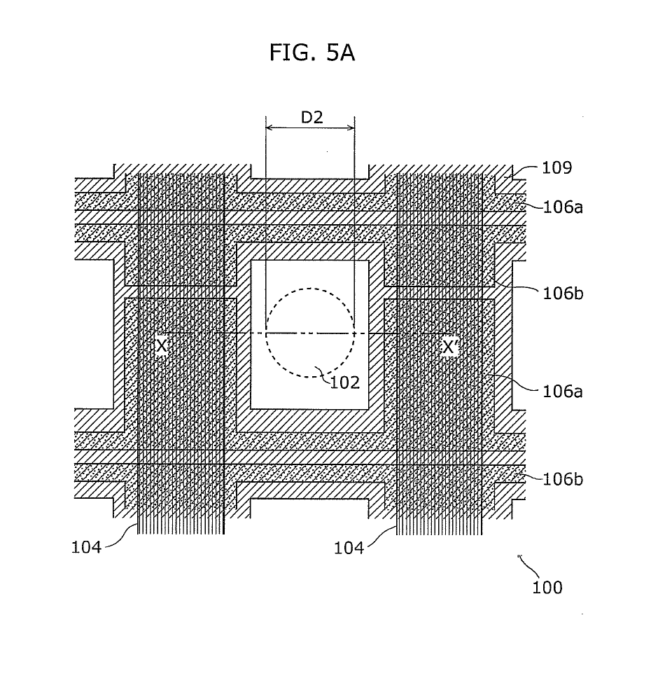

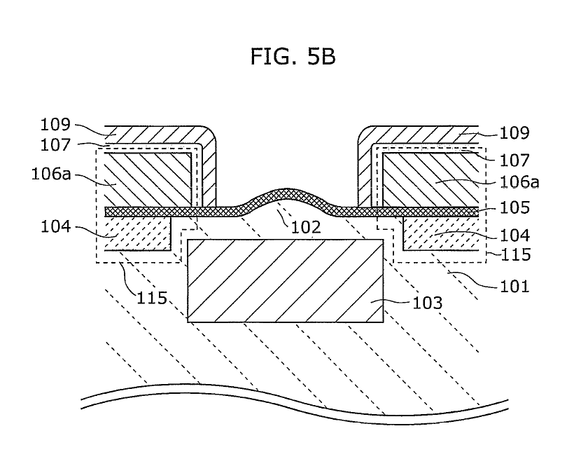

Next, a method of manufacturing the solid-state imaging device 100 according to the first embodiment is described with reference to FIGS. 2 to 5B. FIGS. 2 to 5B show structures, in a manufacturing process, of the solid-state imaging device 100 shown in FIGS. 1A and 1B. FIG. 2 is a cross-section diagram showing a cross-section structure, in a manufacturing process, of the solid-state imaging device 100 shown in FIGS. 1A and 1B. FIGS. 3A, 4A, and 5A are plan views each of which shows a part, in a manufacturing process, of the solid-state imaging device 100 shown in FIG. 2. FIG. 3B is a cross-section diagram showing a part of a cross-section structure taken along line X-X′ of FIG. 3A. FIG. 4B is a cross-section diagram showing a part of a cross-section structure taken along line X-X′ of FIG. 4A. FIG. 5B is a cross-section diagram showing a part of a cross-section structure taken along line X-X′ of FIG. 5A.

First, the semiconductor substrate 101 is prepared (FIG. 2(a)), and on a surface of the semiconductor substrate 101, a thermal oxide film 151 (e.g. silicon oxide) is formed by thermal oxidation (FIG. 2(b)). Subsequently, a resist 152 (e.g. silicon nitride) serving as an insulating film, other than silicon oxide, is formed by chemical vapor deposition (CVD). Next, a resist pattern having a diameter of about 500 nm to 800 nm, for example, is formed by photolithography, and using the resist pattern, anisotropic etching is performed to shape the resist 152 into a circular form (FIG. 2(c)). FIG. 3A is a top view of the structure of FIG. 2(c), and FIG. 3B is an enlarged cross-section diagram of a part of the cross-section structure of FIG. 2(c).

Next, using the thermal oxidation method again, the semiconductor substrate 101 is oxidized. At this time, the surface of the semiconductor substrate 101 which is not covered with the resist 152 is more easily oxidized than the surface of the semiconductor substrate 101 which is covered with the resist 152. Thus, the thermal oxide film 151 becomes thick. In the meantime, the surface of the semiconductor substrate 101 which is covered with the resist 152 is more easily oxidized as the distance from an end of the bottom surface of the resist 152 is shorter. That is, on the surface of the semiconductor substrate 101 covered with the resist 152, the thermal oxide film 151 closer to the end of the bottom surface of the resist 152 is thicker. As a result, the convex part 102 is formed in the surface of the semiconductor substrate 101 (FIG. 2(d)). FIG. 4A is a top view of the structure of FIG. 2(d), and FIG. 4B is an enlarged cross-section diagram of a part of the cross-section structure of FIG. 2(d).

Subsequently, the thermal oxide film 151 and the resist 152 are removed to form the semiconductor substrate 101 having the convex part 102 (FIG. 2(e)).

Next, the insulating film 105 is formed by thermal oxidation on the surface of the semiconductor substrate 101 having the convex part 102 (FIG. 2(f)).

Subsequently, various resist patterns are formed on and ions are injected into the semiconductor substrate 101. By doing so, the light-receiving unit 103 and the transfer channel 104 are formed. A conductive film such as a polysilicon film is then formed on the insulating film 105, after which a part of the conductive film is separated so that the first transfer electrode 106a and the second transfer electrode 106b are formed. Furthermore, the insulating film 107 is formed and then, using a CVD method or the like, a silicon nitride film is formed as the antireflection film 108 over the entire surface and then etched by photolithography so that the antireflection film 108 covers at least part of the top surface of the light-receiving unit 103. Subsequently, a tungsten film is formed as the photo-shield film 109 over the entire surface and then etched by photolithography so that the photo-shield film 109 is formed so as to cover the first transfer electrode 106a and the second transfer electrode 106b (FIG. 2(g)). FIG. 5A is a top view of the structure of FIG. 2(g), and FIG. 5B is an enlarged cross-section diagram of a part of the cross-section structure of FIG. 2(g).

Next, a BPSG film is deposited as the insulating film 110 using a CVD method or the like, after which a recess that is concave downward is formed above the light-receiving unit 103 by a thermal flow (FIG. 2(h)). Subsequently, a silicon nitride film 111′ is deposited using a CVD method or the like so as to fill the recess that is concave downward. Next, the silicon nitride film 111′ is planarized, and the silicon nitride film 111′ is deposited more. Next, above the light-receiving unit 103, a resist pattern having a diameter of about 800 nm to 1800 nm, for example, is formed by lithography and then baked so as to form a hemispherical resist 153 (FIG. 2(i)).

After this, anisotropic etching is performed to etch the silicon nitride film 111′ and the resist 13 so that the surface of the silicon nitride film 111′ is shaped into an upwardly convex form. As a result, the in-layer lens 111 is formed (FIG. 2(j)). Next, the planarizing film 112 is applied, and the color filter 113 and the microscope lens 114 are formed sequentially (FIG. 2(k)).

Through the above process, the solid-state imaging device 100 shown in FIGS. 1A and 1B is formed.

As above, the method of manufacturing the solid-state imaging device 100 according to the first embodiment of the present invention includes: shaping a surface of the semiconductor substrate 101 so as to have curvatures of upward convex curves in a matrix, by selectively oxidizing the surface of the semiconductor substrate 101 to form the thermal oxide film 151 and then removing the thermal oxide film 151, as shown in FIGS. 2(c) and 2(d); and forming the plurality of light-receiving units 103, each of which converts incident light to signal charges, below regions of the surface of the semiconductor substrate 101 which include regions having the curvatures of upward convex curves in the matrix, as shown in FIG. 2(g). In other words, the method includes: a first step of forming, in a matrix, the plurality of convex parts 102, each of which protrudes from the surface of the semiconductor substrate 101 and has a smooth curved surface, by forming the thermal oxide film 151 that varies in thickness measured from the surface of the semiconductor substrate 101 (FIG. 2(d)) and then removing the thermal oxide film 151; and a second step of forming, below the respective convex parts 102, the plurality of light-receiving units 103 that convert incident light into signal charges (FIG. 2(g)).

With this, it is possible to manufacture the solid-state imaging device 100 including the convex parts 102, each of which protrudes from the surface of the semiconductor substrate 101 and has a smooth curved surface, without using any special equipment but by an ordinary method of manufacturing a semiconductor. That is, the solid-state imaging device 100 can be manufactured which is capable of not only improving the light collection efficiency using the in-layer lens 111 above the convex part 103, but also guiding light obliquely incident on the surface of the semiconductor substrate 101 into the light-receiving unit 103 at an angle closer to the vertical by refracting the light by the convex part 102. Thus, with the method of manufacturing the solid-state imaging device 100 according to an implementation of the present invention, it is possible to manufacture the solid-state imaging device 100 capable of further improving the sensitivity while reducing degradation of the smear characteristics.

### Second Embodiment

A solid-state imaging device according to the second embodiment of the present invention is almost the same as the solid-state imaging device 100 according to the first embodiment, except the light-collecting structure above the light-receiving unit 103. Specifically, unlike the solid-state imaging device 100 according to the first embodiment, the solid-state imaging device according to the second embodiment includes a high refractive film and a low refractive film instead of the insulating film 110 and the in-layer lens 111. The high refractive film is provided above the semiconductor substrate 101 for each of the light-receiving units 103 and is formed of an optically transparent film having a columnar shape. The low refractive film covers the side surface of the high refractive film and has a refractive index lower than that of the high refractive film.

With this, the solid-state imaging device according to the second embodiment has an optical wavelength above the light-receiving unit 103 so that light can be totally reflected on the interface between the low refractive film and the high refractive film serving as the optical waveguide, and thereby guided to the surface of the semiconductor substrate 101, and is capable of guiding light obliquely incident on the surface of the semiconductor substrate 101 into the light-receiving unit 103 at an angle closer to the vertical by refracting the light by the convex part 102. Thus, as in the case of the solid-state imaging device 100 according to the first embodiment, the solid-state imaging device according to the second embodiment is capable of improving the sensitivity while reducing degradation of the smear characteristics.

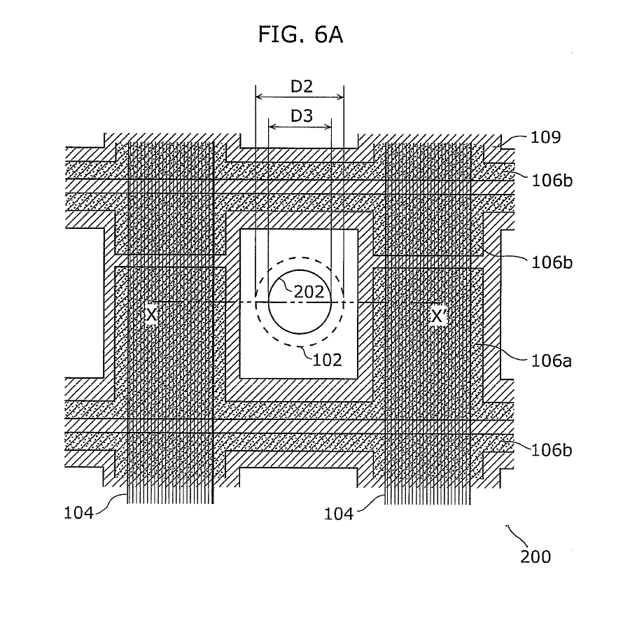

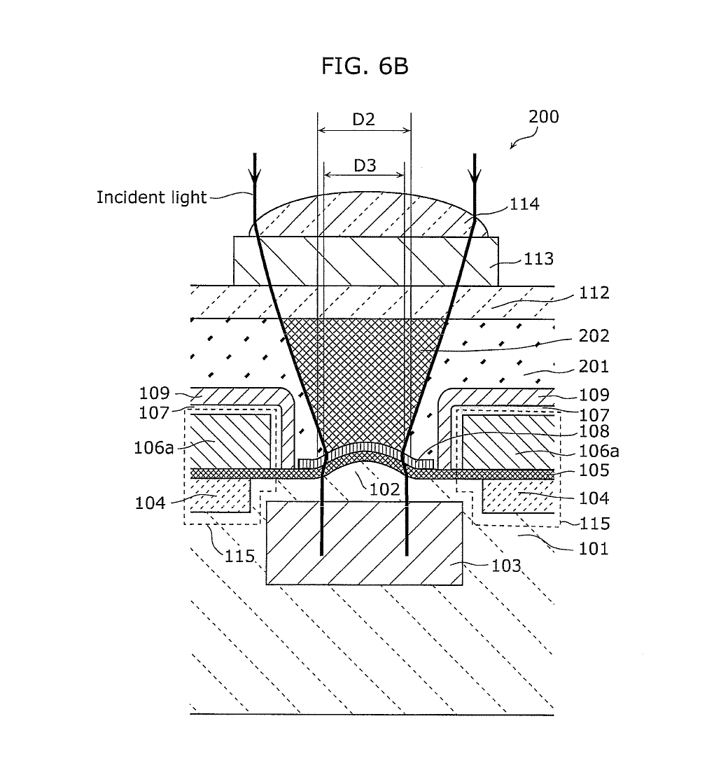

The following describes, with reference to FIGS. 6A and 6B, the solid-state imaging device according to the second embodiment, mainly its differences from the solid-state imaging device 100 according to the first embodiment.

FIG. 6A is an enlarged plan view of a part of the solid-state imaging device according to the second embodiment, and specifically is a plan view showing a structure centered on a single pixel of the solid-state imaging device 200. In this figure, a structure of a part of a pixel adjacent to the single pixel is also shown. FIG. 6B is a cross-section diagram showing a cross-section structure taken along line X-X′ of FIG. 6A, and the bold line in this figure indicates a path of the incident light.

Structures that are the same as in the first embodiment are not described, and the following describes only differences between the first embodiment and the second embodiment.

As shown in FIGS. 6A and 6B, unlike the solid-state imaging device 100 shown in FIGS. 1A and 1B, the solid-state imaging device 200 according to the present embodiment includes the low refractive film 201 and the high refractive film 202 instead of the insulating film 110 and the in-layer lens 111.

The low refractive film 201 is formed on the insulating film 105, the antireflection film 108, and the photo-shield film 109, and defines a shape of the high refractive film 202 having a columnar shape. This low refractive film 201 is formed of a material having a lower refractive index than that of the high refractive film 202, and preferably formed of silicon oxide. That is, the low refractive film 201 covers the side surface of the high refractive film 202 and has a lower refractive index than that of the high refractive film 202. The low refractive film 201 has a thickness of preferably 200 nm to 1500 nm and more preferably around 1000 nm.

The high refractive film 202 is provided above the semiconductor substrate 101 for each of the light-receiving units 103, and formed of an optically transparent film having a columnar shape. The high refractive film 202 is formed on the antireflection film 108 and constitutes an optical waveguide in combination with the low refractive film 201, and guides light incident on this high refractive film 202 into the light-receiving unit 103 of the semiconductor substrate 101 by totally reflecting the light on the interface between the high refractive film 202 and the low refractive film 201. This high refractive film 202 is formed of an optically transparent material having a high refractive index, and particularly formed of, preferably, silicon nitride.

Furthermore, the diameter D3 of the light-receiving unit 103-side end of this high refractive film 202 and the diameter D2 of the convex part 102 of the semiconductor substrate 101 preferably have a relation represented by (Expression 2) below.

D2≧D3 (Expression 2)

As above, the solid-state imaging device 200 according to the second embodiment includes: the high refractive film 202 provided above the semiconductor substrate 101 for each of the light-receiving units 103 and formed of an optically transparent film having a columnar shape; and the low refractive film 201 covering the side surface of the high refractive film and having a lower refractive index than a refractive index of the high refractive film.

With this, the solid-state imaging device 200 according to the second embodiment has an optical wavelength above the light-receiving unit 103 so that light can be totally reflected on the interface between the low refractive film 201 and the high refractive film 202 serving as the optical waveguide, and thereby guided to the surface of the semiconductor substrate 101, and is capable of guiding the light obliquely incident on the surface of the semiconductor substrate 101 into the light-receiving unit 103 at an angle closer to the vertical by refracting the light by the convex part 102. Thus, the solid-state imaging device 200 according to the second embodiment is capable of improving the sensitivity while reducing degradation of the smear characteristics, as in the case of the solid-state imaging device 100 according to the first embodiment.

Next, a method of manufacturing the solid-state imaging device 200 according to the second embodiment is described. Note that the process before forming the photo-shield film 109 (FIG. 2(g)) is the same as in the method of manufacturing the solid-state imaging device 100 according to the first embodiment and therefore not described.

In the method of manufacturing the solid-state imaging device 200 according to the second embodiment, after the photo-shield film 109 is formed, a silicon oxide film that is a material of the low refractive film is deposited using a CVD method or the like. Next, above the light-receiving unit 103, a resist pattern with an opening having a diameter of about 1000 nm to 1500 nm, for example, is formed by lithography, and anisotropic etching is then performed to remove the silicon oxide film which is present above the light-receiving unit 103. Thus, the low refractive film 201 having a through hole is formed above the light-receiving unit 103. At this time, the diameter of the opening at the light-receiving unit 103-side end of the low refractive film 201 is preferably around 300 nm to 700 nm. Subsequently, a silicon nitride film that is a material of the high refractive film 202 is deposited using a CVD method or the like so that the opening of the low refractive film 201 is filled up with the silicon nitride film, and by removing the silicon nitride film which is present on the low refractive film 201, the high refractive film 202 having a columnar shape is formed. Next, the planarizing film 112 is applied, and the color filter 113 and the microscope lens 114 are formed sequentially.

Through the above process, the solid-state imaging device 200 shown in FIGS. 6A and 6B is formed.

As above, in the method of manufacturing the solid-state imaging device 200 according to the second embodiment of the present invention, the low refractive film 201 is formed first and the high refractive film 202 is then formed by filling the through hole of the low refractive film 201 with the silicon nitride film.

With this, it is possible to form an optical waveguide which employs the low refractive film 201 and the high refractive film 202, without using any special equipment but by an ordinary method of manufacturing a semiconductor. Thus, it is possible to manufacture a solid-state imaging device with high sensitivity, which reduces degradation of the smear characteristics.

It is to be noted that the present invention is not limited to the above descriptions in the first and second embodiments, and various modifications can be made within the scope of the present invention.

For example, numerical values and materials stated in the above first and second embodiments are illustrative and non-limiting to the present invention.

For example, a solid-state imaging device may include different light-collecting structures; the curved surface of the convex part 102 may be different in shape for each of the wavelength ranges of light to be collected.

While in the drawings the corners and sides of each component are shown to be linear, one having round corners and sides for manufacturing reasons is also encompassed within the scope of the present invention.

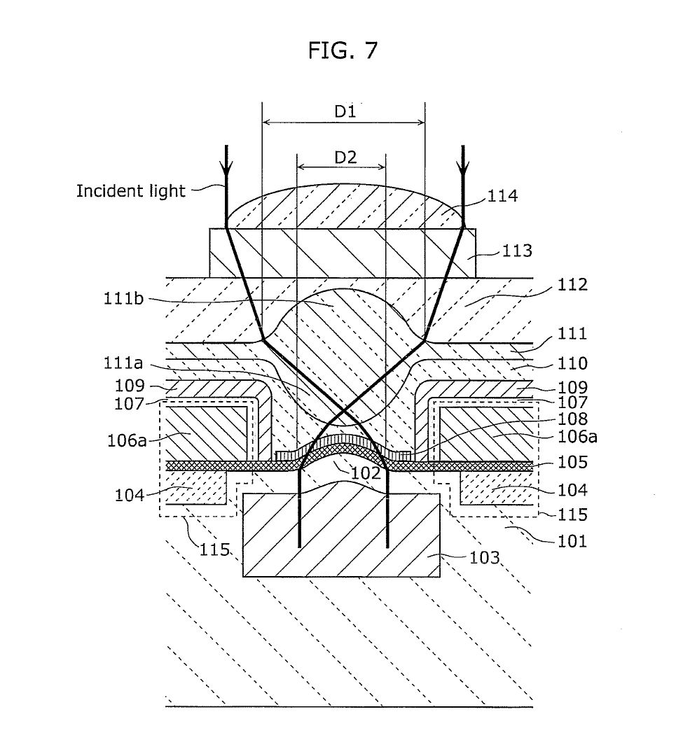

Furthermore, while the top surface of the light-receiving unit 103 is flat in the above embodiments, the surface of the light-receiving unit 103 may be convex as shown in FIG. 7. In other words, the surface of the light-receiving unit 103 may be defined by a smooth curved surface which is convex upward.

While the light-receiving unit 103 is formed inside the semiconductor substrate 101 in FIG. 1B, the light-receiving unit 103 may be formed on the surface of the semiconductor substrate 101. In this case, the top surface of the light-receiving unit 103 may be common with the top surface of the semiconductor substrate 101, and the surface of the light-receiving unit 103 may have an upwardly convex shape.

Furthermore, in the above embodiments, the convex part 102, the first sub-lens part 111a, the second sub-lens part 111b, and the high refractive film 202 each have a substantially circular cross-section when seen in the direction parallel to the semiconductor substrate 101, but this is a non-limiting example. For example, the convex part 102, the first sub-lens part 111a, the second sub-lens part 111b, and the high refractive film 202 may each have a substantially rectangular or square cross-section when seen in the direction parallel to the semiconductor substrate 101.

In addition, while the CCD solid-state imaging device has been described as implementation examples of the present invention, the present invention may also be used in a metal oxide semiconductor (MOS) solid-state imaging device, and in such a case, high sensibility can be attained.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to solid-state imaging devices such as digital still cameras and digital video cameras.

What is claimed is:

1. A solid-state imaging device comprising:
a semiconductor substrate; and
a plurality of light-receiving units formed in a matrix in said semiconductor substrate and configured to convert incident light into signal charges,
wherein said semiconductor substrate includes a plurality of convex parts, each of which protrudes from a surface of said semiconductor substrate and has a smooth curved surface, and
each of said convex parts is positioned corresponding to one of said light-receiving units and formed integrally with said semiconductor substrate.

2. The solid-state imaging device according to claim 1,
wherein each of said light-receiving units has a smooth curved surface which is upwardly convex.

3. The solid-state imaging device according to claim 1, further comprising
a lens formed of a transparent film above each of said convex parts.

4. The solid-state imaging device according to claim 3,
wherein said lens includes silicon nitride.

5. The solid-state imaging device according to claim 3,
wherein, when measured in a direction parallel to said semiconductor substrate, an outer diameter of said lens is equal to or greater than an outer diameter of each of said convex parts.

6. The solid-state imaging device according to claim 3, further comprising
a color filter provided above said semiconductor substrate,
wherein said lens is provided under said color filter.

7. The solid-state imaging device according to claim 1, further comprising:
a high refractive film provided above said semiconductor substrate for each of said light-receiving units and formed of a transparent film having a columnar shape; and
a low refractive film covering a side surface of said high refractive film and having a refractive index lower than a refractive index of said high refractive film.

8. The solid-state imaging device according to claim 7,
wherein said high refractive film includes silicon nitride.

9. The solid-state imaging device according to claim 7,
wherein said low refractive film includes silicon oxide.

10. The solid-state imaging device according to claim 7,
wherein an outer diameter of an end of said high refractive film on a side of each of said light-receiving units is equal to or smaller than an outer diameter of each of said convex parts measured in a direction parallel to said semiconductor substrate.

11. A method of manufacturing a solid-state imaging device, comprising:
forming a plurality of convex parts in a matrix by forming an oxide film which varies in thickness measured from a surface of a semiconductor substrate, and then removing the oxide film, the convex parts protruding from the surface of the semiconductor substrate and each having a smooth curved surface; and
forming, below the respective convex parts, a plurality of light-receiving units that convert incident light into signal charges.
